(19) United States
(12) Patent Application Publication
(10) Pub. No.: US 2018/0102318 A1
(43) Pub. Date: Apr. 12, 2018

(54) COMPOUND RESISTOR STRUCTURE FOR SEMICONDUCTOR DEVICE

(71) Applicant: GLOBALFOUNDRIES INC., Grand Cayman (KY)

(72) Inventors: Cathryn J. Christiansen, Huntington, VT (US); Hanyi Ding, Colchester, VT (US); Baozhen Li, South Burlington, VT (US)

(21) Appl. No.: 15/291,275

(22) Filed: Oct. 12, 2016

(51) Int. Cl. H01L 23/522; H01L 23/525; H01L 23/528; H01L 49/02; H01L 23/367; H01L 21/768; H01L 21/48

(52) U.S. Cl. CPC H01L 23/5228; H01L 23/5226; H01L 23/5256; H01L 21/4871; H01L 28/20; H01L 23/3675; H01L 21/76895; H01L 23/528

(57) ABSTRACT

A compound resistor structure can use multiple electrically conductive pads connected by resistive elements to provide the equivalent resistance of a conventional resistor while spreading generated heat over a larger area. An array of pads and resistive elements can create larger resistances, metal connectors between rows of pads allowing current to flow from a first pad in a first row to a last pad in a last row via pads and resistive elements in each row. Fuses connecting pads in such an array can be included to allow tuning of resistance and/or other electrical properties.

### BACKGROUND

### Technical Field

The present disclosure relates to elements of photolithographically manufactured integrated circuits (ICs), and more specifically, to the fabrication of a resistor structure with improved heat dissipation, which may be particularly applicable in higher power and alternating current (AC) applications.

### Related Art

Semiconductor devices, particularly ICs, are manufactured by depositing, patterning, and removing layers of material. Most ICs include resistors, which are typically formed using polysilicon on an insulator material. Typically, such a resistor includes two electrically conductive pads electrically connected by a single resistive element. However, resistors formed in such a manner can be limited in the amount of current that they may carry lest they overheat and degrade or cause other heat-related problems to neighboring structures.

### SUMMARY

A first aspect of the disclosure is directed to a compound resistor structure for a semiconductor device. A first layer can include a plurality of pads of a first electrically conductive material, the plurality of pads including a first pad, a last pad, and at least one interposed pad. A second layer can include at least two resistive elements of an electrically resistive material, each resistive element extending between and electrically connecting two of the plurality of pads such that the first pad is electrically connected to the last pad through the at least one interposed pad via the at least two resistive elements.

A second aspect of the disclosure includes a method of making a compound resistor structure in a semiconductor device. A plurality of pads can be formed from a layer of a first electrically conductive material. The pads can be spaced apart from each other and can include a first pad, at least one interposed pad, and a last pad. A plurality of resistive elements can also be formed, the plurality of resistive elements electrically connecting the first pad to the last pad via the at least one interposed pad.

A third aspect of the disclosure can include a compound resistor structure in which an array of pads can be formed from a first electrically conductive material. The array can include at least two rows of pads including a first row and a last row, each row including a first end pad at a first end of the respective row and a second end pad at a second end of the respective row opposite the respective first end. A first pad of the array can be a first end pad of the first row, and a last pad of the array being a second end pad of the last row. At least one electrical connector between adjacent rows can electrically connect at least one pad of a row to at least one pad of each adjacent row. A plurality of resistive elements can successively connect the pads of each row such that a first pad in a row is electrically connected to a last pad in a row through at least two of the plurality of resistive elements and at least one pad between the first pad of the respective row and the last pad of the respective row, and such that the first pad of the array is electrically connected to the last pad of the array through the plurality of resistive elements, the array of pads, and the at least one electrical connector.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIG. 1 shows a schematic top view of a basic example of a compound resistor structure for a semiconductor device according to embodiments of the disclosure.

FIG. 2 shows a schematic isometric view of the example shown in FIG. 1 of a compound resistor structure for a semiconductor device according to embodiments of the disclosure.

FIG. 3 shows a schematic side view of the example shown in FIGS. 1 and 2 of a compound resistor structure for a semiconductor device.

FIG. 4 shows a schematic top view of another basic example of a compound resistor structure for a semiconductor device according to embodiments of the disclosure.

FIG. 5 shows a schematic isometric view of the example shown in FIG. 4 of a compound resistor structure for a semiconductor device according to embodiments of the disclosure.

FIG. 6 shows a schematic side view of the example shown in FIGS. 4 and 5 of a compound resistor structure for a semiconductor device.

FIG. 7 shows a schematic top view of another example of a compound resistor structure for a semiconductor device according to embodiments of the disclosure.

FIG. 8 shows a schematic isometric view of the example shown in FIG. 7 of a compound resistor structure for a semiconductor device according to embodiments of the disclosure.

FIG. 9 shows a schematic side view of the example shown in FIGS. 7 and 8 of a compound resistor structure for a semiconductor device according to embodiments of the disclosure.

FIG. 10 shows a schematic top view of a further example of a compound resistor structure for a semiconductor device according to embodiments of the disclosure.

FIG. 11 shows a schematic isometric view of the example shown in FIG. 10 of a compound resistor structure for a semiconductor device according to embodiments of the disclosure.

FIG. 12 shows a schematic side view of the example shown in FIGS. 10 and 11 of a compound resistor structure for a semiconductor device according to embodiments of the disclosure.

FIG. 13 shows a schematic top view of a further example of a compound resistor structure for a semiconductor device according to embodiments of the disclosure.

FIG. 14 shows a schematic isometric view of the example shown in FIG. 13 of a compound resistor structure for a semiconductor device according to embodiments of the disclosure.

FIG. 15 shows a schematic side view of the example shown in FIGS. 13 and 14 of a compound resistor structure for a semiconductor device according to embodiments of the disclosure.

FIG. 16 shows a schematic top view of a further example of a compound resistor structure for a semiconductor device according to embodiments of the disclosure.

FIG. 17 shows a schematic isometric view of the example shown in FIG. 16 of a compound resistor structure for a semiconductor device according to embodiments of the disclosure.

FIG. 18 shows a schematic side view of the example shown in FIGS. 16 and 17 of a compound resistor structure for a semiconductor device according to embodiments of the disclosure.

FIG. 19 shows a schematic side view of another example of a compound resistor structure for a semiconductor device according to embodiments of the disclosure, here including vias to electrically connect parts of the structure.

FIG. 20 shows a schematic isometric view of a further example of a compound resistor structure for a semiconductor device according to embodiments of the disclosure illustrating stacking of components and electrically connecting parts with vias.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

Various examples are disclosed herein of a resistor structure that uses standard materials and processes in new patterns or arrangements to provide resistors with improved heat dissipation. In a simplest form, a typical resistor having two conductive elements bridged by a resistive element is broken into three conductive elements and two resistive elements, which can be arranged in a linear fashion for convenience, but need not be. Also for convenience, each conductive element can be called a pad. Thus, a first end pad, an interposed or middle pad, and a second end pad can be arranged in alignment and spaced apart with a first resistive element electrically connecting the first end pad and the middle pad, and a second resistive element electrically connecting the middle pad and the second end pad. Additional pads and resistive elements can be used for additional capacity in a single line or row, and additional rows can be used and connected to each other for further capacity. To provide tuning of a compound resistor structure according to embodiments, particularly where two or more rows are employed, one or more fuses can be placed to connect corresponding pads of adjacent rows. Each fuse shunts current from one row to the next, and by blowing a fuse, the resistance of the compound resistor structure can be increased. In addition, to provide additional heat dissipation, one or more heat sinks or “bars” can be included adjacent or even interspersed between portions of a compound resistor structure according to embodiments. Such bars can be, for example, electrically isolated elements of the same material or layer used to form the pads. Advantageously, compound resistor structures according to embodiments disclosed herein can be formed using steps easily integrated into middle-end-of-line or back-end-of-line processes, and can include metal gates formed during deposition of a metal layer. With additional heat dissipation, a resistor structure according to embodiments can be operated at higher power than conventional resistor structures. Further, embodiments as disclosed herein can be fabricated using known semiconductor fabrication techniques.

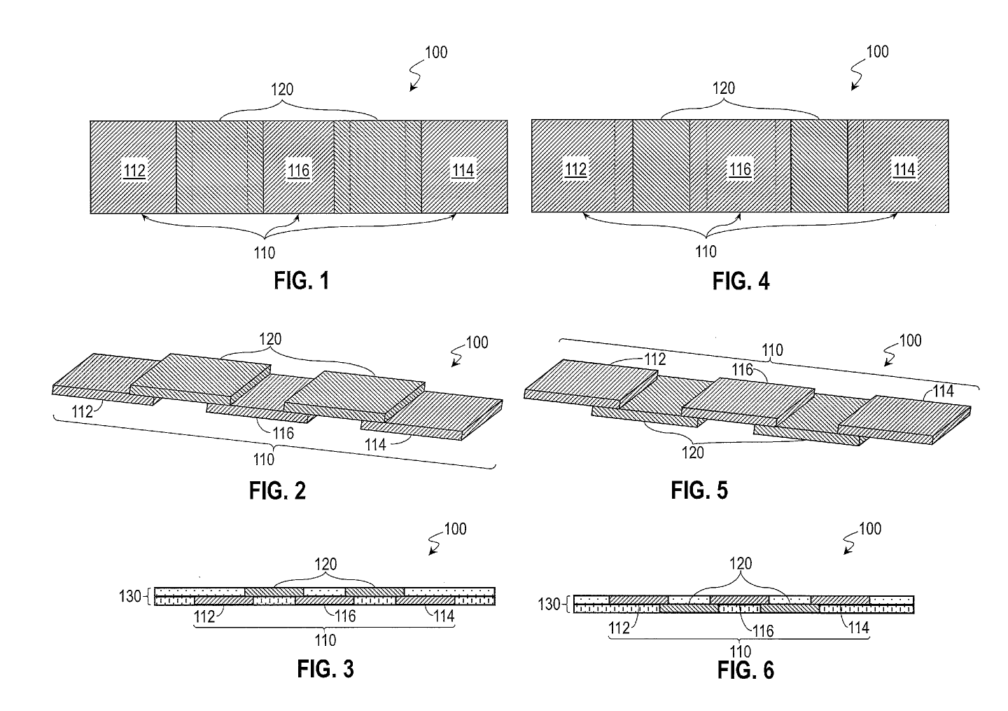

As seen in FIGS. 1-6, a compound resistor 100, also referred to herein as a compound resistor structure, can include a plurality of pads 110 of a first electrically conductive material, such as formed in a first layer including such material, and at least two resistive elements 120 of an electrically resistive material, such as formed in a second layer including such material. As seen in FIGS. 1-3, pads 110 can be below resistive elements 120, but as seen in FIGS. 4-6, pads 110 can also be above resistive elements 120 if so desired and/or suitable for a particular implementation. In the examples of FIGS. 1-6, the plurality of pads 110 is shown including three pads 110 arranged in a row or line for ease of explanation. A first end pad 112 can be disposed at a first end of the line of pads 110, and a second end pad 114 can be disposed at a second, opposite end of the line of pads 110. First end pad 112 can be a first pad of compound resistor 100 and can also be a first contact pad, and second end pad 114 can be a last pad of compound resistor structure 100 and can also be a second contact pad. Each contact pad can be connected to another device, power source, ground, or other electrical element as may be appropriate. At least one interposed pad 116, which can also be referred to as an intervening pad, can be arranged between first end pad 112 and second end pad 114 in spaced apart relationship. Pads 110 can be electrically isolated from each other except for electrical connections established by resistive elements 120. For example, a first electrically insulative material, such as silicon dioxide (SiO₂) or any other suitable insulator, can be deposited between pads 110 and/or resistive elements 120 as illustrated by additional layers 130 in FIGS. 3 and 6. For clarity of illustration, such additional materials and/or layers in which the components of this example might be formed, such as is illustrated by layers 130 in FIGS. 3 and 6, have been omitted from FIGS. 1, 2, 4, and 5, but it should be readily apparent to those skilled in the art that one or more layers can be present in, around, above, and/or below compound resistor structure 100, such as device layers, insulator layers, etc.

More specifically, each resistive element 120 can extend between and electrically connect two pads 110, though each connected pair of pads 110 is not unique. That is, one resistive element 120 can connect first end pad 112 and interposed pad 116, and another resistive element 120 can connect interposed pad 116 and second end pad 114, so that interposed pad 116 is connected to two resistive elements 120. The first pad, first end pad 112, is thereby electrically connected to the last pad, second end pad 114, through interposed pad 116 via resistive elements 120. While pads 110 are here shown as equal in size with equal space between them, this need not be the case, and pads 110 can have varied thickness, length, width, and/or space therebetween if desired and/or appropriate. Further, it should be understood that more pads 110 and resistive elements 120 can be employed to provide a compound resistor 100 with desired electrical and/or thermal properties. In addition, pads 110 and resistive elements 120 need not be arranged in a row, but can be arranged in any shape or pattern as may be suitable or desired, such as, but not limited to, an “L” shape or a polygon, for example.

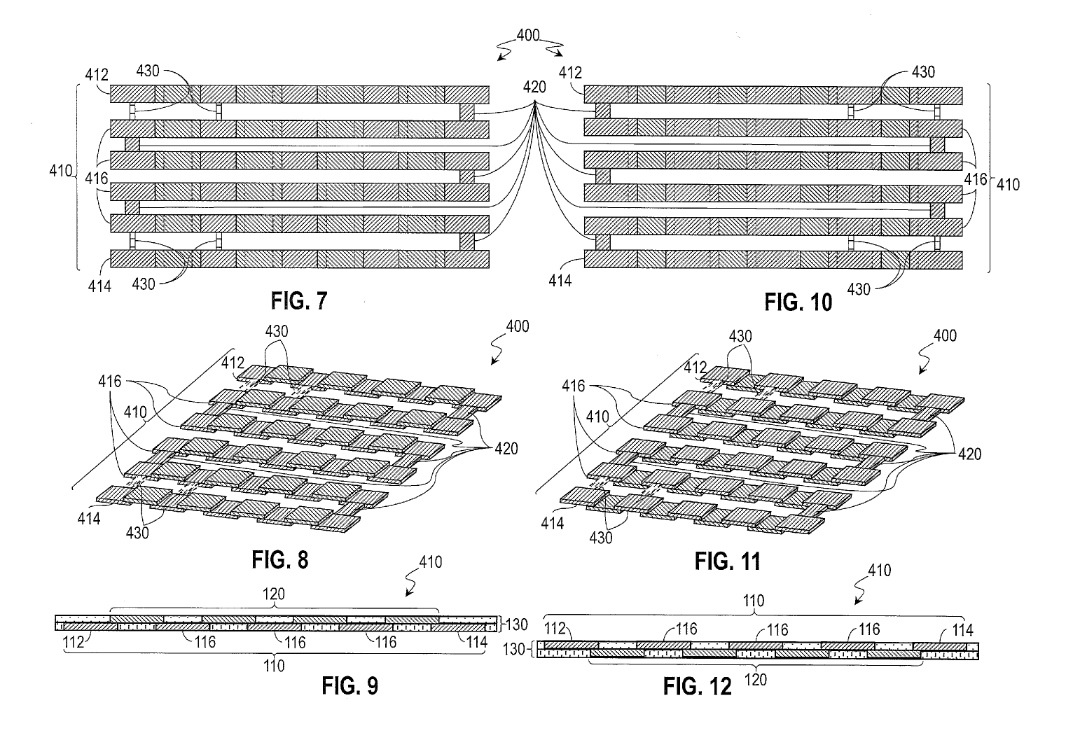

FIGS. 7-12 show two arrangements of another example of a compound resistor structure 400 according to embodiment, FIGS. 7-9 showing pads 110 below resistive elements 120, and FIGS. 10-12 showing pads 110 above resistive elements 120. As seen in FIGS. 7-12, effectively, multiple instances of the example compound resistor 100 of FIGS. 1-3 or FIGS. 4-6 can be arranged to form adjacent rows 410 of pads and resistive elements, rows 410 being arranged in spaced apart, parallel relation with at least a first row 412 and a last row 414, and can include at least one intervening row 416, which can also be referred to herein as an interposed row. In this description, rows (of pads) can also be referred to as lines (of pads) as in the description of the example of FIGS. 1-6, above.

As particularly shown in FIGS. 9 and 12, each row 410 can include pads 110 and resistive elements 120 connecting pads 110 in much the same manner as the example of FIGS. 1-6, with first and second end pads 112, 114 and intervening pads 116. Pads 110 can be electrically isolated from each other, as can resistive elements 120. For example, a first electrically insulative material, such as silicon dioxide (SiO₂) or any other suitable insulator, can be deposited between pads 110 and/or resistive elements 120 as illustrated by additional layers 130 in FIGS. 9 and 12. In addition, rows 410 can be electrically isolated from each other by such layer(s) of insulative material, though layers 130 can include other materials and/or devices as suitable and/or desired. For clarity of illustration, such additional materials and/or layers in which the components of this example might be formed, such as is illustrated by layers 130 in FIGS. 9 and 12, have been omitted from FIGS. 7, 8, 10, and 11, but it should be readily apparent to those skilled in the art that one or more layers can be present in, around, above, and/or below compound resistor structure 400, such as device layers, insulator layers, etc.

For convenience, rows 410 in FIGS. 7, 8, 10, and 11 can be viewed as having alternating orientation so that a second end pad 114 of first row 412 is aligned with a first end pad 112 of an adjacent row, here an intervening row 416, whose second end pad 114 is aligned with a first end pad 112 of a next adjacent row, and so on. Other arrangements can be made within the scope of embodiments, but this arrangement is efficient in the amount of material used to form electrical connectors 420 and compound resistor structure 400 overall.

As seen in FIGS. 7, 8, 10, and 11, electrical connectors 420 can each extend between and electrically connect a pad of one line and a pad of another line so that current can flow through at least a portion of first row or line 412 to last row or line 414, and through at least a portion of any intervening row or line 416 therebetween. In the example shown, a first pad of compound resistor structure 400 can be the first end pad 112 of first line or row 412 of the at least two lines 410 of pads, and the last pad of compound resistor structure 400 can be a second end pad 114 of last row or line 414 of the at least two lines 410. As shown, electrical connectors 420 can each engage pads of adjacent lines to electrically connect the first pad through at least a portion of first line 412, through at least a portion of any interposed line 416, and through at least a portion of last line 414 to the last pad. To allow tuning of electrical properties of compound resistor structure 400, at least one fuse 430 can each be formed between two pads, here shown as electrically connecting adjacent pads of adjacent lines. It should be noted that a fuse 430 can electrically connect any two pads of compound resistor structure 400, even two pads in one line if desired and/or appropriate.

The compound resistor structure 400 of FIGS. 7-12 can also be described as including an array of pads formed from a first electrically conductive material, the array including at least two rows of pads 410 including a first row 412 and a last row 414. As seen in FIGS. 9 and 12, each row 410 of pads 110 can include a first end pad 112 at a first end of the respective row 410 and a second end pad 114 at a second end of the respective row 410, and at least one intervening pad 116, which can also be termed at least one interposed pad, between the first end pad 112 and the second end pad 114. A first pad of the array can be a first end pad of first row 412, and a last pad of the array can be a second end pad of last row 414. At least one electrical connector 420 between adjacent rows can electrically connect at least one pad 110 of a row 410 to at least one pad 110 of each adjacent row 410. A plurality of resistive elements 120, which can be above (FIG. 9) or beneath (FIG. 12) the pad layer (pads 110), can successively connect the pads 110 of each row 410 such that a first end pad 112 in a row 410 is electrically connected to a second end pad 114 of the same row 410 through at least two of the plurality of resistive elements 120 and at least one intervening pad 116 of the respective row. The first pad of the array can thus be electrically connected to the last pad of the array through the plurality of resistive elements 120, pads 110 of the array of pads, and the at least one electrical connector 420.

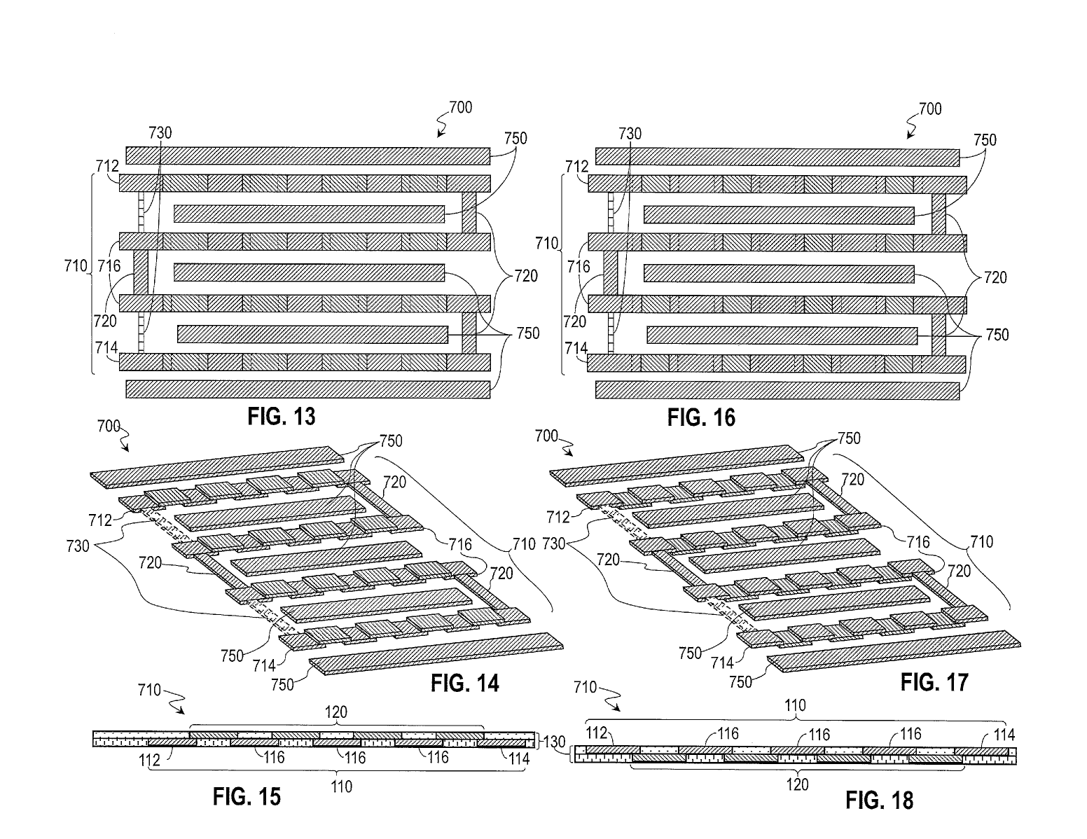

FIGS. 13-18 show two arrangements of another example of a compound resistor structure 700 according to embodiments disclosed herein, FIGS. 13-15 showing pads 110 below resistive elements 120 and FIGS. 16-18 showing pads 110 below resistive elements 120. Like the example of FIGS. 7-12, multiple rows or lines 710 of pads can be arranged in spaced apart, parallel relation, with a first row or line 712, a last row or line 714, and at least one interposed or intervening row or line 716. Electrical connectors 720 can extend between and electrically connect adjacent lines to electrically connect a first pad in first row 712 to a last pad in last row 714 through at least a portion of first row or line 712, at least a portion of any intervening or interposed row or line 716, and at least a portion of last row or line 714. Also as in the example of FIGS. 4-6, fuses 730 can electrically connect pairs of pads, such as pads of adjacent rows or lines 710, to allow tuning of electrical properties of compound resistor structure 700. Here, however, compound resistor structure 700 can include at least one heat sink 750 adjacent rows or lines 710. In addition, rows or lines 710 can be farther apart to accommodate at least one heat sink 750 therebetween. Each heat sink 750 can be electrically isolated from lines or rows 710, connectors 720, and fuses 730. In addition, in embodiments, one or more heat sink 750 can engage a thermally conductive layer (not shown) beneath or above compound resistor structure 700 to enhance heat dissipation.

While only one heat sink 750 is shown between each pair of adjacent rows or lines 710, it should be apparent that more than one heat sink 750 could be used, and that the size and arrangement thereof can also be varied as may be desired and/or suitable without departing from the scope of embodiments disclosed herein. Further, while a heat sink 750 is shown adjacent each of the “top” and “bottom” of compound resistor structure 700, more than one can be placed in either location, either can be omitted, or both can be omitted as may be suitable and/or desired. In addition, while heat sinks 750 are shown as being parallel to rows or lines 710, they need not be, and one or more heat sinks 750 can be arranged at other angles along rows or lines 710, or even along ends of rows or lines 710, such as perpendicular to rows or lines 710.

As with the example of a compound resistor structure 400 of FIGS. 7-12, the example of a compound resistor structure 700 shown in FIGS. 13-18 can also be described as including an array of pads formed from a first electrically conductive material, the array including at least two rows of pads 710 including a first row 712 and a last row 714. As seen in FIGS. 15 and 18, each row 710 of pads 110 can include a first end pad 112 at a first end of the respective row 710 and a second end pad 114 at a second end of the respective row 710, and at least one intervening pad 116, which can also be termed at least one interposed pad, between the first end pad 112 and the second end pad 114. A first pad of the array can be a first end pad of first row 712, and a last pad of the array can be a second end pad of last row 714. At least one electrical connector 720 between adjacent rows can electrically connect at least one pad 110 of a row 710 to at least one pad 110 of each adjacent row 710. A plurality of resistive elements 120, which can be above (FIG. 15) or beneath (FIG. 18) the said pads, can successively connect the pads 110 of each row 710 such that a first end pad 112 in a row 710 is electrically connected to a second end pad 114 of the same row 710 through at least two of the plurality of resistive elements 120 and at least one intervening pad 116 of the respective row. The first pad of the array can thus be electrically connected to the last pad of the array through the plurality of resistive elements 120, pads 110 of the array of pads, and the at least one electrical connector 720. As in the previous examples, pads 110 can be electrically isolated from each other, as can resistive elements 120. For example, a first electrically insulative material, such as silicon dioxide (SiO₂) or any other suitable insulator, can be deposited between pads 110 and/or resistive elements 120 as illustrated by additional layers 130 in FIGS. 15 and 18. In addition, rows 710 can be electrically isolated from each other by such layer(s) of insulative material, though layers 130 can include other materials and/or devices as suitable and/or desired. For clarity of illustration, such additional materials and/or layers in which the components of this example might be formed, such as is illustrated by layers 130 in FIGS. 15 and 18, have been omitted from FIGS. 13, 14, 16, and 17, but it should be readily apparent to those skilled in the art that one or more layers can be present in, around, above, and/or below compound resistor structure 700, such as device layers, insulator layers, etc.

A method of making a compound resistor structure in a semiconductor device, such as the examples shown in the FIGS., can include forming a plurality of pads from a layer of a first electrically conductive material. This can include forming the pads spaced apart from each other, and the plurality of pads can include a first pad, at least one interposed pad, and a last pad. For example, a metal layer, such as of copper (Cu), aluminum (Al), manganese (Mn), and/or another suitable metal, can be deposited using well known semiconductor fabrication techniques to form the plurality of pads. In particular, embodiments contemplate deposition during back end of line (BEOL) processes. “Deposition” as used throughout the disclosure may include any now known or later developed techniques appropriate for the material to be deposited, including, but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

After or before the plurality of pads has been formed, embodiments can include forming a plurality of resistive elements electrically connecting the first pad to the last pad via the at least one interposed pad. That is, each resistive element can engage two pads to electrically connect them, so that the first pad can be electrically connected to an interposed pad by one resistive element, and each interposed pad can be electrically connected to another pad, such as another interposed pad or to the last pad, by another resistive element. In embodiments, forming the plurality of resistive elements can include depositing a layer of resistive material over the pads and removing the resistive material from at least a portion of each pad of the plurality of pads, thereby forming with remaining resistive material the plurality of resistive elements that electrically connect adjacent pads of the plurality of pads. As with the plurality of pads, the plurality of resistive elements can be formed using well known photolithographic and semiconductor fabrication techniques. The plurality of resistive elements can be formed from any suitable material, such as, but not limited to, tungsten silicide (WSi) and/or tantalum nitride (TaN). Silicide may be formed using any now known or later developed technique, e.g., performing an in-situ pre-clean, depositing a metal such as titanium, nickel, cobalt, etc., annealing to have the metal react with silicon, and removing unreacted metal.

To electrically isolate the pads in the plurality of pads from each other, embodiments can include, before forming the plurality of resistive elements, depositing a layer of a first electrically insulative material between the pads and removing any of the first electrically insulative material covering top surfaces of the pads of the plurality of pads. Again, well known semiconductor fabrication processes can be used to achieve the deposition and removal, and the first electrically insulative material can include any suitable material, such as silicon dioxide, for example. Alternatively, the first electrically insulative material could be deposited before formation of the plurality of pads, and cavities can be formed to receive the plurality of pads, with excess of the first electrically conductive material being removed before deposition of the resistive elements. Further, where the resistive elements are formed below the pads, embodiments can include depositing a layer of resistive material before forming the plurality of pads, depositing a layer of a first electrically insulative material between the resistive elements of the plurality of resistive elements and removing any of the first electrically insulative material covering top surfaces of the resistive elements of the plurality of resistive elements. Forming the plurality of pads can include depositing a layer of a first electrically conductive material over the resistive elements of the plurality of resistive elements and removing the first electrically conductive material from at least a portion of each resistive element of the plurality of resistive elements, thereby forming with remaining first electrically conductive material the plurality of pads, pads of the plurality of pads thereby being electrically connected by resistive elements

In a simplest embodiment, the plurality of pads can be arranged in a line, but the plurality of pads can also be arranged in more than one line, the lines spaced apart from each other and connected by electrical connectors.

Embodiments including multiple lines of pads effectively create an array of pads arranged in rows and columns when viewed from a point along a line perpendicular to a plane connecting the top surfaces of the pads. Thus, a method of making a compound resistor structure according to embodiments where the plurality of pads includes at least one line of pads can include forming an array of pads from a first electrically conductive material, the array including at least two rows of pads including a first row and a last row. Each row can include a first end pad at a first end of the respective row and a second end pad at a second end of the respective row opposite the respective first end. A first pad of the array can be a first end pad of the first row, and a last pad of the array can be a second end pad of the last row.

To increase heat dissipation, the method according to embodiments can further comprise forming at least one heat sink, each heat sink adjacent and electrically isolated from a respective one of the at least one line of pads. The forming the at least one heat sink and the forming of the plurality of pads can be performed simultaneously, the at least one heat sink thereby being formed from the same material as the plurality of pads. In addition, where the at least one line of pads includes at least two lines of pads, forming the at least one heat sink can include forming a heat sink between and electrically isolated from two adjacent lines. For example, in a compound resistor structure according to embodiments including three lines of pads, a heat sink can be formed between the first line of pads and an adjacent interposed line of pads, and another heat sink can be formed between the interposed line of pads and the last row of pads.

In embodiments including multiple lines of pads, so that the first pad is in a first line of pads and the last pad is in a last line of pads, the method can include forming at least one electrical connector between adjacent lines of pads so that electrical current can flow from the first pad to the last pad via at least a portion of each line of pads and the at least one electrical connector. Thus, in a compound resistor structure according to embodiments including three lines of pads, a pad of the first line of pads can be electrically connected to a pad of the interposed line of pads by a first electrical connector, and a pad of the interposed line of pads can be electrically connected to a pad of the last line of pads by a second electrical connector. See, for example, the example of FIGS. 7-12, where an electrical connector 420 connects the second end pad of first line of pads 412 to the first end pad of interposed line of pads 416, another electrical connector 420 connects the second end pad of that interposed line of pads 416 to the first end pad of a next interposed line of pads 416, etc., until the first end pad of the last line of pads 414 is connected to the last interposed line of pads 416 by a last of the electrical connectors 420. Thus, the first pad is connected to the last pad by at least a portion of each line of pads 410, including respective resistive elements, and electrical connectors 420. In addition, forming the at least one electrical connector can include forming at least one fuse between two pads. For example, again referring to the example of FIGS. 7-12, a fuse 430 can connect corresponding pads of adjacent lines of pads 410, though other embodiments could include a fuse 430 connecting pads in one line of pads 410, or connecting lines of pads 410 separated by one or more interposed lines of pads 416. Electrical connectors and/or fuses can also be included in the example of FIGS. 13-18 using much the same steps.

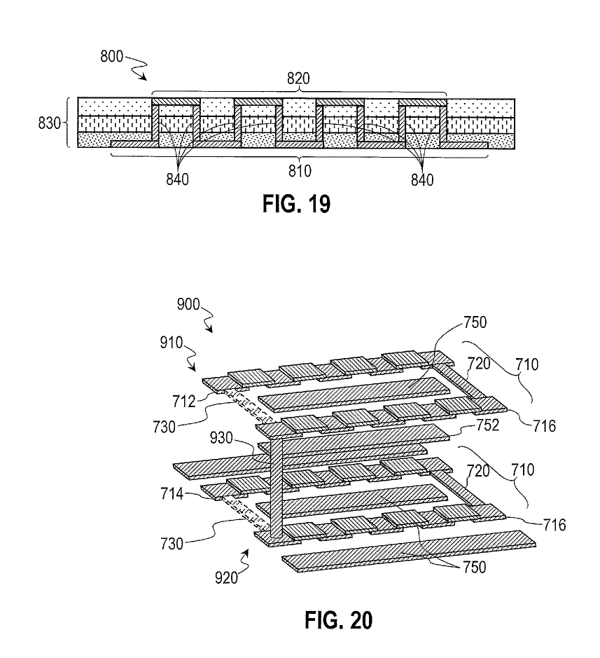

While embodiments have been shown as having the pads and resistive elements in direct contact, such as in adjacent layers, this need not be the case. As seen in FIG. 19, a compound resistor structure 800 can include pads 810 spaced apart from resistive elements 820, such as by one or more material layers 830, which can include, for example, device layers, insulator layers, or other material/layers as may be suitable, desired, and/or convenient. Vias 840 can electrically connect pads 810 and resistive elements 820 in such arrangements. Further, such arrangements can include heat sinks 850 in any suitable location between pads 810 and resistive elements 820 as opposed to in a plane of either pads 810 or resistive elements 820. Vias 840 in such arrangements can be formed by well known techniques in semiconductor fabrication as will be readily understood by one skilled in the art.

Additionally, while rows of pads have been shown as in a single plane, one or more rows can be above or below one or more other rows and connected by vias. For example, as shown in FIG. 20, a compound resistor structure 900 can include a first layer 910 of rows 710 of pads and resistive elements (110 and 120 of FIG. 15, for example), and one or more additional layers 920 of rows 710 of pads and resistive elements (110 and 120 of FIG. 15, for example). For clarity of illustration, additional materials and/or layers in which the components of this example might be formed, such as is illustrated in FIG. 19, have been omitted, but it should be readily apparent to those skilled in the art that one or more layers can extend between first layer 910 and one or more additional layers 920, such as device layers, insulator layers, etc.

In FIG. 20, two layers of rows are shown to illustrate how the example of FIGS. 13-18 could be implemented with multiple layers of rows to conserve area of the compound resistor structure 900. Thus, whereas in FIGS. 13-15 the first two rows 710 are connected to the last two rows 710 by an electrical connector 720 in the same layer as rows 710, in the example of FIG. 19, that electrical connector can be replaced with a via 930 connecting pads of the intervening rows 716. That is, first layer 910 can include first row 712 and a first intervening row 716, and second layer 920 can include a second intervening row 716 and last row 714, the second end pad (114 in FIG. 15, for example) of the first intervening row 716 being connected to the first end pad (112 in FIG. 15, for example) by via 930. As in the example of FIGS. 13-15, fuses 730 can be included to tune properties of resistor 900, though in embodiments these could extend between layers. Further, one or more heat sinks 750 can be arranged in one or more layers 910, 920, and/or one or more heat sinks can be arranged between layers 910, 920, such as is illustrated by heat sink 752.

Accordingly, the described disclosure provides a compound resistor structure that can include fuses for tuning electrical properties thereof and heat sinks for enhanced heat dissipation. By breaking a conventional resistor of a given resistance into multiple parts, a given resistance can be used at higher current and/or power levels than would be possible with a conventional resistor. In addition, compound resistor structures according to embodiments can be used in alternating current (AC) applications in which conventional resistors cannot.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The methods and/or structures as described above are, e.g., used in the fabrication of integrated circuit chips, in a packaged form (3D package). The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. In a semiconductor device, a compound resistor structure comprising:
a first layer including a plurality of pads of an electrically conductive metal or mixture of metals, the plurality of pads including a first pad, a last pad, and at least one interposed pad; and
a second layer including at least two resistive elements of an electrically resistive material, each resistive element extending between, directly contacting and electrically connecting two of the plurality of pads such that the first pad is electrically connected to the last pad through the at least one interposed pad via the at least two resistive elements.

2. The compound resistor structure of claim 1, wherein the plurality of pads is arranged in a line with the first pad being a first end pad at a first end of the line and the last pad being a second end pad at a second, opposite end of the line.

3. The compound resistor structure of claim 2, wherein the plurality of pads is arranged in at least two lines in spaced apart, parallel relation, the first pad being a first end pad of a first line of the at least two lines and the last pad being a second end pad of a last of the at least two lines, and wherein at least one electrical connector each engages pads of adjacent lines to electrically connect the first pad through at least a portion of the first line, through at least a portion of any interposed line, and through at least a portion of the last line to the last pad.

4. The compound resistor structure of claim 3, wherein at least one line is vertically spaced apart from others of the at least two lines and is electrically connected thereto by at least one via.

5. The compound resistor structure of claim 2, further comprising at least one fuse electrically connecting one of the pads to another of the pads.

6. The compound resistor structure of claim 2, further comprising at least one heat sink adjacent and electrically isolated from the at least one line of pads.

7. The compound resistor structure of claim 6, wherein the at least one heat sink is formed from the same layer of material as the plurality of pads.

8. The compound resistor structure of claim 1, wherein at least one resistive element is vertically spaced apart from a pad to which it is electrically connected by a via.

9. A method of making a compound resistor structure in a semiconductor device, the method comprising:
forming a plurality of pads from a layer of an electrically conductive metal or mixture of metals, the pads being spaced apart from each other and including a first pad, at least one interposed pad, and a last pad; and
forming a plurality of resistive elements, the resistive elements and pads being arranged such that the resistive elements electrically connect the first pad to the last pad via the at least one interposed pad.

10. The method of claim 9, further comprising, before forming the plurality of resistive elements, depositing a layer of a first electrically insulative material between the pads of the plurality of pads and removing any of the first electrically insulative material covering top surfaces of the pads of the plurality of pads, and wherein forming the plurality of resistive elements includes depositing a layer of resistive material over the pads of the plurality of pads and removing the resistive material from at least a portion of each pad of the plurality of pads, thereby forming with remaining resistive material the plurality of resistive elements that electrically connect adjacent pads of the plurality of pads.

11. The method of claim 9, further comprising forming the plurality of resistive elements before forming the plurality of pads, including depositing a layer of resistive material before forming the plurality of pads, depositing a layer of a first electrically insulative material between the resistive elements of the plurality of resistive elements and removing any of the first electrically insulative material covering top surfaces of the resistive elements of the plurality of resistive elements, and wherein forming the plurality of pads includes depositing a layer of a first electrically conductive material over the resistive elements of the plurality of resistive elements and removing the first electrically conductive material from at least a portion of each resistive element of the plurality of resistive elements, thereby forming with remaining first electrically conductive material the plurality of pads, pads of the plurality of pads thereby being electrically connected by resistive elements.

12. The method of claim 9, wherein the plurality of pads includes at least one line of pads, the method further comprising forming at least one heat sink, each heat sink adjacent and electrically isolated from a respective one of the at least one line of pads.

13. The method of claim 12, wherein the forming the at least one heat sink and the forming of the plurality of pads are performed simultaneously, the at least one heat sink thereby being formed from the same material as the plurality of pads.

14. The method of claim 12, wherein the at least one line of pads includes at least two lines of pads, and the forming at least one heat sink includes forming a heat sink between and electrically isolated from two adjacent lines.

15. The method of claim 12, wherein the at least one line of pads includes at least a first line of pads and a last line of pads, and forming the plurality of pads includes forming at least one electrical connector between adjacent lines of pads so that electrical current can flow from the first pad to the last pad via at least a portion of each line of pads, respective resistive elements, and the at least one electrical connector.

16. The method of claim 15, further comprising forming at least one fuse between two pads.

17. The method of claim 15, wherein the at least one line of pads includes a line of pads vertically spaced apart from others of the at least one line of pads and that is electrically connected thereto by at least one via.

18. (canceled)

19. (canceled)

20. (canceled)

21. The compound resistor structure of claim 1, wherein the metal is selected from the group consisting of copper (Cu), aluminum (Al) and manganese (Mn), and the mixture of metals is at least two selected from the group consisting of copper (Cu), aluminum (Al) and manganese (Mn).
